(19) United States
(12) Patent Application Publication
(10) Pub. No.: US 2025/0188347 A1
(43) Pub. Date: Jun. 12, 2025

(54) QUANTUM DOT AND METHOD FOR PREPARATION THEREOF AND LIGHT-EMITTING DEVICE

(71) Applicant: TCL TECHNOLOGY GROUP CORPORATION, Huizhou, Guangdong (CN)

(72) Inventor: Yuan WANG, Huizhou, Guangdong (CN)

(73) Assignee: TCL TECHNOLOGY GROUP CORPORATION, Huizhou, Guangdong (CN)

(21) Appl. No.: 18/713,708

(22) PCT Filed: Oct. 19, 2022
(86) PCT No.: PCT/CN2022/126244

§ 371 Date: Dec. 12, 2024

(30) Foreign Application Priority Data
Dec. 30, 2021 (CN) 202111651458.X

(51) Int. Cl. C09K 11/88; H10K 50/115

(52) U.S. Cl. CPC C09K 11/883; H10K 50/115

(57) ABSTRACT

The disclosure provides a quantum dot and method for preparation thereof, and a light-emitting device. The method for preparation of the quantum dot includes: injecting a precursor solution into a reaction channel of a microfluidic reactor, and reacting at a preset reaction temperature to generate a quantum dot. The precursor solution includes a first solvent and a second solvent. A boiling point of the first solvent is higher than a reaction temperature, and a boiling point of the second solvent is lower than the reaction temperature. Continuous, large-scale synthesis preparation of quantum dot and micron-scale accurate control are achieved.

This application claims priority of the Chinese patent application with the Chinese Patent Application No. 202111651458.X, filed in the China National Intellectual Property Administration on Dec. 30, 2021, and entitled “QUANTUM DOT AND METHOD FOR PREPARATION THEREOF AND LIGHT-EMITTING DEVICE”, which is incorporated herein by reference in its entirety.

### TECHNICAL FIELD

The present disclosure relates to the field of quantum dot technologies, and more particularly, to a quantum dot, a method for preparation thereof and a light-emitting device.

### BACKGROUND

Quantum dots (QDs), known as semiconductor nanocrystals, refer to semiconductor materials with a size between 1 nm and 10 nm. Because the size of the quantum dot is smaller than or close to the Bohr radius of excitons, the movement of electrons in all directions is limited. The electronic energy level structure changes from continuous energy levels to discrete energy levels, resulting in quantum confinement effects. Because of its special electronic structure and photoelectric properties, quantum dots have been widely studied in the field of photovoltaic and light-emitting display.

Up to now, various quantum dots with different structures and properties can be easily synthesized by solution method. The batch reaction with flask as the main synthesis tool has made an important contribution to the development and improvement of quantum dot synthesis technology, however, its inherent shortcomings of the limit the large-scale production of quantum dot and the in-depth research on the mechanism of quantum dot reaction. For example, the complexity of the batch synthesis process leads to low yields and difficulties in scaling up, the instability of the process leads to poor repeatability and difficult to suppress side reactions, and the heterogeneity of physicochemical parameters of reaction environment (such as precursor volume, injection rate, concentration gradient of the reaction environment, and temperature gradient of the reaction environment are difficult to control uniformly).

### SUMMARY

### Technical Problem

There are some defects in the preparation of a quantum dot by traditional batch reactions, which limit the large-scale production of quantum dots and the in-depth study of the reaction mechanism of quantum dots

### TECHNICAL SOLUTION FOR PROBLEM

### Technical Solution

Therefore, the present disclosure provides a quantum dot, a method for preparation thereof and a light-emitting device.

Embodiments of the present disclosure provide a method for preparing a quantum dot, which includes: injecting a precursor solution into a reaction channel of a microfluidic reactor, and reacting at a preset reaction temperature to form a quantum dot. The precursor solution includes a first solvent and a second solvent, a boiling point of the first solvent is higher than a reaction temperature, and a boiling point of the second solvent is lower than the reaction temperature.

Alternatively, in some embodiments of the present disclosure, a volume ratio of the first solvent to the second solvent is (7-8):(2-3).

Alternatively, in some embodiments of the present disclosure, the reaction temperature is 250° C.-300° C.

Alternatively, in some embodiments of the present disclosure, the first solvent is selected from one or more of octadecene, liquid paraffin, oleamine, oleic acid, hexadecyl phosphoric acid, dodecylamine, and dodecyl mercaptan.

Alternatively, in some embodiments of the present disclosure, the second solvent is selected from an alkane with a carbon chain of 6 to 13 carbon atoms in length or an olefin with a carbon chain of 6 to 13 carbon atoms in length.

Alternatively, in some embodiments of the present disclosure, the second solvent is selected from one or more of n-hexane, n-heptane, n-octane, n-nonane, n-decane, n-undecane, and n-dodecane.

Alternatively, in some embodiments of the present disclosure, a flow rate of injecting a precursor solution into a microfluidic reactor ranges from 1 to 10 μL/s.

Alternatively, in some embodiments of the present disclosure, a residence time of the precursor solution in the reaction channel is 5˜40 minutes.

Alternatively, in some embodiments of the present disclosure, the quantum dot is selected from one or more of a blue light quantum dot, a green light quantum dot, or a red light quantum dot.

Alternatively, in some embodiments of the present disclosure, the blue light quantum dot is selected from one or more of ZnTe, ZnSe, CdZnS, CdZnSe, ZnSeTe, ZnSTe, and ZnSeTe; the green light quantum dot is selected from one or more of CdSe, CdZnSeS, CdZnSe, and ZnSeTe; the red light quantum dot is selected from one or more of CdSe, CdTe, CdSeTe, ZnCdSe, CdSeS, and CdZnSeS.

Alternatively, in some embodiments of the present disclosure, before injecting a precursor solution into a reaction channel of a microfluidic reactor, the method further includes: mixing a cationic precursor and an anionic precursor with a first solvent and a second solvent to obtain the precursor solution.

Alternatively, in some embodiments of the present disclosure, before mixing a cationic precursor and an anionic precursor with a first solvent and a second solvent, the method further includes: preparing the cation precursor and preparing the anion precursor.

Alternatively, in some embodiments of the present disclosure, preparing the cation precursor includes: mixing a metal salt or a metal oxide with a precursor solvent, heating to a temperature of 125˜180° C. in an inert gas atmosphere, and heat preservation reacting for 30˜90 minutes to obtain the cation precursor in a solution state.

Alternatively, in some embodiments of the present disclosure, the metal salt is selected from one or more of a zinc salt, a cadmium salt, an acetate, a palmitate, a stearate, and a halogen salt; and/or, the metal oxide is selected from one or two of zinc oxide and cadmium oxide; and/or, the precursor solvent includes one or more of the first solvent and the second solvent; and/or, a concentration range of a cation in the cationic precursor solution is 0.05˜1 mol/L.

Alternatively, in some embodiments of the present disclosure, the precursor solvent includes oleic acid and octadecene, and a volume ratio of oleic acid to octadecene is (1:1)˜(1:5).

Alternatively, in some embodiments of the present disclosure, preparing the anion precursor includes: mixing, dispersing and dissolving a non-metallic powder and a ligand in an inert gas atmosphere under a temperature of 80˜150° C. to obtain the anionic precursor solution in a solution state.

Alternatively, in some embodiments of the present disclosure, the ligand is selected from one or more of trioctyl phosphine, tributylphosphine, and trihexylphosphine; and/or, the non-metallic powder is selected from one or more of a selenium powder, a sulfur powder, and a tellurium powder.

Correspondingly, the embodiments of the present disclosure further provide a quantum dot, wherein the quantum dot is prepared by the method above.

Alternatively, in some embodiments of the present disclosure, the quantum dot is selected from one or more of a single structure quantum dot and a core-shell structure quantum dot; the single structure quantum dot is selected from one or more of a group II-VI compound, a group III-V compound, and a group I-III-VI compound; the group II-VI compound is selected from one or more of CdSe, CdS, CdTe, ZnSe, ZnS, CdZnS, CdZnSe, CdZnTe, ZnSeS, ZnSeS, CdSeTe, ZnTeS, CdSeS, CdSeTe, CdSeS, CdSeTe, CdTeS, CdZnSeS, CdZnSeS, CdZnSeTe, and CdZnSTe; the group III-V compound is selected from one or more of InP, InAs, GaP, AlN, AlP, InAsP, InNP, InNSb, GaAlNP, and InAlNP; the group I-III-VI compound is selected from one or more of CuInS₂, CuInSe₂, and AgInS₂; a core of the core-shell structure quantum dot is selected from any one of the single structure quantum dot, and a material of a shell of the core-shell structure quantum dot is selected from one or more of CdS, CdTe, CdSeTe, CdZnSe, CdZnS, CdSeS, ZnSe, ZnSeS, and ZnS.

Correspondingly, the embodiments of the present disclosure further provide a light-emitting device including a light-emitting layer, wherein a material of the light-emitting layer is the quantum dot above.

### BENEFICIAL EFFECTS OF INVENTION

### Beneficial Effects

The method for preparing a quantum dot of the present disclosure includes: injecting a precursor solution into a reaction channel of a microfluidic reactor, and reacting at a preset reaction temperature to form a quantum dot. The precursor solution includes a first solvent and a second solvent, a boiling point of the first solvent is higher than a reaction temperature, and a boiling point of the second solvent is lower than the reaction temperature. Continuous and large-scale synthesis preparation of the quantum dot may be realized by using a microfluidic reactor for reaction, and accurate control of a fluid reaction may be achieved at a micron-scale, thereby improving a synthesis efficiency of the reaction. By using the first solvent with a boiling point higher than the reaction temperature and the second solvent with a boiling point lower than the reaction temperature as a mixed solvent of the precursor solution, a viscosity of the precursor solution in the reaction channel may be reduced, a residence time of the precursor solution in a microfluidic reaction channel and a packing efficiency of a reactant in an inner wall of the reaction channel may be reduced, and the second solvent will vaporize at the reaction temperature. A reaction system in the microchannel may improve a mixing effect of the reactant in the reaction channel through gas-liquid mixing, thereby improving a reaction rate and a uniformity of a size distribution of the quantum dot prepared.

### BRIEF DESCRIPTION OF THE DRAWINGS

### Description of the Drawings

In order to more clearly explain the technical solutions in the embodiments of the present disclosure, the figures to be used in the description of the embodiments are briefly described below. It is apparent that the figures in the following description are merely some embodiments of the present disclosure. For those skilled in the art, without involving any creative effort, other figures may be obtained based on these figures.

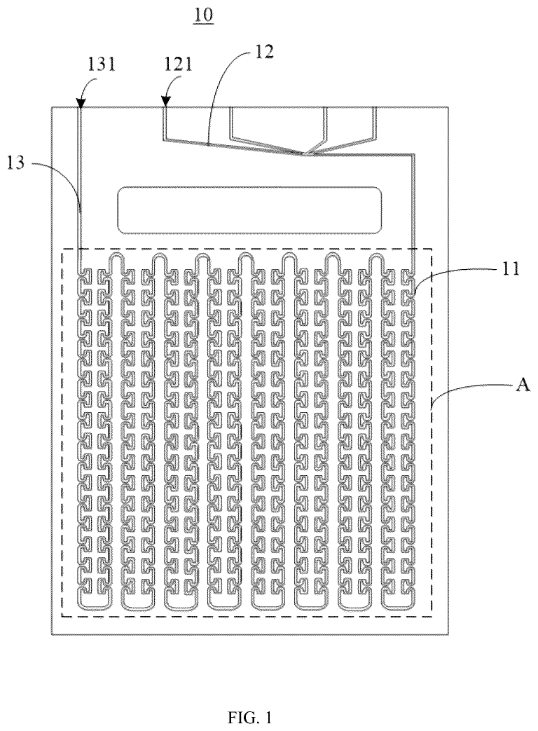

FIG. 1 is a structural schematic diagram of a microfluidic reactor according to an embodiment of the present disclosure.

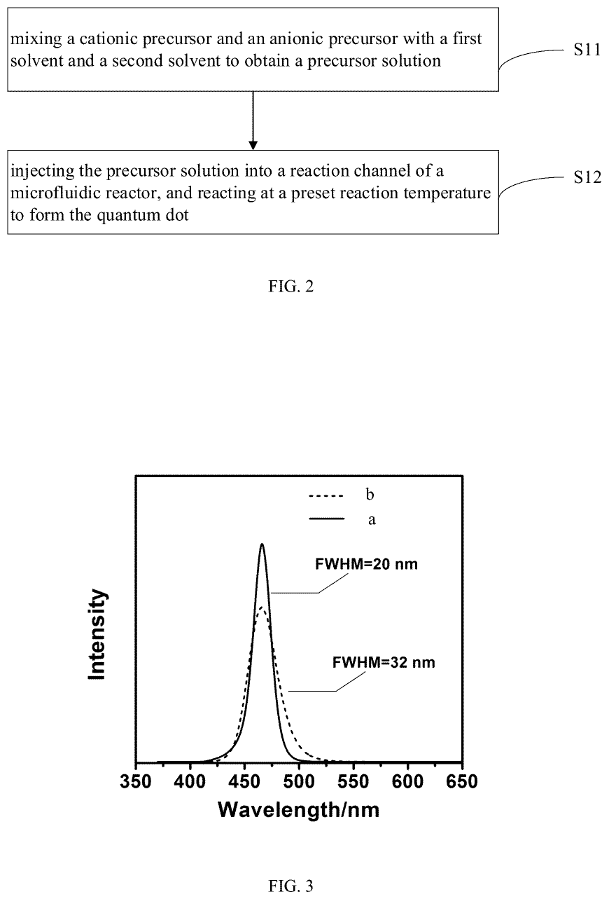

FIG. 2 is a flowchart of a method for preparing a quantum dot according to an embodiment of the present disclosure.

FIG. 3 is a fluorescence emission spectrogram corresponding to Example 1 and Comparative Example 1.

### EMBODIMENTS OF THE PRESENT DISCLOSURE

Technical solutions in embodiments of the present disclosure will be clearly and completely described below with reference to the figures in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

In addition, it should be understood that the specific embodiments described herein are for the sole purpose of illustrating and explaining the present disclosure, and are not intended to limit the present disclosure. In the present disclosure, unless otherwise stated, the directional words used such as “up” and “down” are specifically the surface directions in the attached figures. Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6 has specifically disclosed su-branges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association relationship of associated objects, and means that there may be three relationships, for example, “A and/or B” may refer to three relationships: for example, A exists alone, A and B exist at the same time, and B exists alone, where A and B may be singular or plural.

In the present disclosure, the terms “at least one” refer to one or more, and “a plurality of/multiple” refers to two or more. The terms “at least one”, “at least one of the followings”, or the like, refer to any combination of the items listed, including any combination of a single item or a plurality of items. For example, “at least one of a, b, or c” or “at least one of a, b, and c” may refer to: a, b, c, a-b (i.e., a and b), a-c, b-c, or a-b-c, where a, b, and c may be single or plural (multiple).

The present disclosure provides a method for preparing a quantum dot, which includes: injecting a precursor solution into a reaction channel of a microfluidic reactor, and reacting at a preset reaction temperature to generate a quantum dot. The precursor solution includes a first solvent and a second solvent, a boiling point of the first solvent is higher than a reaction temperature, and a boiling point of the second solvent is lower than the reaction temperature.

In embodiments of the present disclosure, continuous and large-scale synthesis preparation of the quantum dot may be realized by using a microfluidic reactor for reaction, and accurate control of a fluid reaction may be achieved at a micron-scale, thereby improving a synthesis efficiency of the reaction. Moreover, the second solvent will gasify at the reaction temperature, and a reaction system in a microchannel may improve a mixing effect of reactant in the reaction channel through gas-liquid mixing, thereby improving a reaction rate and a uniformity of a size distribution of quantum dot prepared. In addition, the gasification of part of solvents may enhance an inert atmosphere in the reaction channel, and reduce the damage of water and oxygen in the reaction channel to the synthesis of the quantum dot. In addition, a boiling point of a solvent is positively correlated with a viscosity of the solvent to a certain extent, that is, the higher the boiling point, the greater the viscosity. Compared with a traditional reaction using a high boiling point solvent only, in the embodiments, the first solvent with a boiling point higher than the reaction temperature and the second solvent with a boiling point lower than the reaction temperature are used as a mixed solvent of the precursor solution, the addition of the second solvent with a lower boiling point may reduce the viscosity of the precursor solution in the reaction channel to a certain extent, thereby reducing a residence time of the precursor solution in a microfluidic reaction channel, and reducing a packing efficiency of a reactant on an inner wall of the reaction channel.

The microfluidic reactor in the present disclosure includes the reaction channel, and a heating zone can be arranged at a corresponding position of the reaction channel, and the reaction channel and the fluid flowing therein can be heated to the reaction temperature or the reaction temperature to carry out the reaction. The quantum dot is prepared by a microfluidic reaction in the microfluidic reactor. Moreover, the microfluidic reaction can also be called a microflow reaction, a microchannel reaction, a fluid micro-reaction, and the like. Different from a traditional batch reaction, a reaction solution of the microfluidic reaction flows continuously, and target products are prepared by continuous synthesis through a mixed reaction of a continuous fluid or a reaction of the continuous fluid under heating or another reaction conditions in the microchannel.

It can be understood that, the microfluidic reactor of the present disclosure may be a microfluidic reactor known in the prior art. In addition to the reaction channel, the microfluidic reactor of the present disclosure may further include other portions, such as a plurality of injection channels, a plurality of mixing channels, a plurality of detection zones, and the like.

In a specific embodiment, the microfluidic reactor is referred to FIG. 1, and FIG. 1 is a structural schematic diagram of a microfluidic reactor according to an embodiment of the present disclosure. The microfluidic reactor 10 has a chip structure, and includes a reaction channel 11, an injection channel 12, and an outflow channel 13. One end of the injection channel 12 is an injection port 121, and another end of the injection channel 12 is communicated with the reaction channel 11. One end of the reaction channel 11 is communicated with the injection channel 12, and another end of the reaction channel 11 is communicated with the outflow channel 13. One end of the outflow channel 13 communicates with the injection channel 12, and another end of the outflow channel 13 is a flow outlet 131. The microfluidic reactor 10 may include a plurality of injection channels 12, but in actual use, one or more of them may be selected to be used as required, and injection ports 121 of other injection channels 12 that are not required to be used may be sealed. The dotted box in FIG. 1 shows a heating zone A corresponding to the reaction channel 11. The reaction channel 11 and a reaction system flowing therein are heated to the reaction temperature by heating the heating zone A.

After a reaction fluid is injected in the microfluidic reactor, it flows out from a tail end of the microfluidic channel of the microfluidic reactor, and the flow outlet can act as a pressure relief port. When a solvent with a low boiling point is gasified at high temperature, because of the existence of the flow outlet at a tail end of the channel, potential danger of high pressure due to solvent gasification will not occur.

Moreover, the first solvent and the second solvent may be a solvent known in the prior art and with a boiling point satisfies the condition above. The solvent known in the prior art includes an aromatic hydrocarbon, an aliphatic hydrocarbon, an alicyclic hydrocarbon, a halogenated hydrocarbon, an alcoholic solvent, an ether, a diol derivative, and other solvents such as acetonitrile, pyridine, and phenol.

In an embodiment, a volume ratio of the first solvent to the second solvent is (7-8):(2-3). Excessive proportion of the second solvent whose boiling point is lower than the reaction temperature will cause the precursor solution to enter the reaction channel with the reaction temperature, and a concentration of the reaction system will be too large due to the gasification of the second solvent, which is not conducive to the synthesis of the quantum dot. However, if the proportion of the second solvent is too small, it will cannot effectively reduce the viscosity of the reaction system and cannot achieve the effect of mixing uniformity.

Moreover, the reaction temperature is correspondingly set according to a synthesis temperature of the quantum dot, for example, it can be an appropriate temperature for synthesizing the quantum dot.

In an embodiment, the reaction temperature is 250° C.-300° C. The temperature range is an appropriate temperature for the synthesis of the quantum. In the temperature range, the precursor solution can react and grow quantum dot quickly and efficiently, thereby improving synthesis efficiency and quantum dot yield. When the reaction temperature is 250° C.-300° C., the precursor solution includes a first solvent and a second solvent, the boiling point of the first solvent is higher than the reaction temperature, and the boiling point of the second solvent is lower than the reaction temperature, thereby, the boiling point of the first solvent is higher than 300° C., and the boiling point of the second solvent is lower than 250° C. Of course, the boiling point of the second solvent cannot be infinitesimal, and the second solvent needs to be liquid at room temperature or at normal temperature, and can be liquid when entering the microfluidic reactor. If the boiling point of the second solvent is too small, the second solvent will be gasified before entering the microfluidic reactor and cannot be used as a solvent.

Specifically, the first solvent may be a hydrocarbon compound including at least one of a linear hydrocarbon compound, a branched hydrocarbon compound, or a monocyclic hydrocarbon compound. That is, the first solvent may be a single solvent, or a mixed solvent formed by two or more solvents. Similarly, the second solvent may be a single solvent, or a mixed solvent formed by two or more solvents. The hydrocarbon compound may be a saturated alkane or an unsaturated alkane, such as an olefin. The monocyclic hydrocarbon compound may be a hydrocarbon compound including a benzene ring. Specifically, the first solvent may include at least one of octadecene, liquid paraffin, oleamine, oleic acid, hexadecyl phosphoric acid, dodecylamine, and dodecyl mercaptan.

The second solvent may be an alkane with a carbon chain of 6 to 13 carbon atoms in length or an olefin with a carbon chain of 6 to 13 carbon atoms in length. That is, the second solvent may be selected from an alkane having a carbon chain length about 6 to 13 carbon atoms or an olefin having a carbon chain length about 6 to 13 carbon atoms, such as n-hexane, n-heptane, n-octane, n-nonane, n-decane, n-undecane, and n-dodecane.

In an embodiment, the precursor solution is injected into the microfluidic reactor at a flow rate ranging from 1 to 10 μL/s. If the flow rate is too low, the flows in all channels including the reaction channel in the microfluidic reactor will be slow, and the quantum dot formed by a precursor reaction cannot flow out of each channel smoothly and continuously, thereby resulting in detention and other conditions that affect a synthesis efficiency of the quantum dot. Excessive flow rate requires a large pressure on the microfluidic reactor, thus lead to excessive pressure in each channel of the microfluidic reactor, and may cause damage to the microfluidic reactor.

In an embodiment, a residence time of the precursor solution in the reaction channel is 5˜40 minutes. For a continuous fluid reaction, the residence time refers to a residence time of the material particles in the reactor or the reaction channel, that is, a time difference between the material particles entering the reactor or the reaction channel and leaving the reactor or the reaction channel. The material particles are smallest units of fluid flow, for example a cation configured to synthesis the quantum dot. In the embodiment, the residence time of the precursor solution in the reaction channel is the same as the residence time of the material particles in the reactor or the reaction channel. The residence time is within the range of 5˜40 minutes, thereby it can ensure that precursors in the precursor solution fully reacted in a fluid flowing out of the reaction channel, and the fluid will not stay for too long to lead to an agglomeration of the quantum dot. Too short residence time may lead to insufficient reaction time, and poor mass and wide size distribution of quantum dots. However, excessive residence time may lead to the quantum dot formed in the solution agglomerate in the reaction channel, thus reducing the quality of the quantum dot that synthesized. Moreover, excessive residence time may further reduce the synthesis efficiency of the quantum dot.

The quantum dot synthesized in the present disclosure may be selected from at least one of a blue light quantum dot, a green light quantum dot, or a red light quantum dot. A structure of the blue light quantum dot may be ZnTe, ZnSe, CdZnS, CdZnSe, ZnSeTe, ZnSTe, ZnSeTe, and the like. A structure of the green light quantum dot may be CdSe, CdZnSeS, CdZnSe, ZnSeTe, and the like. A structure of the red light quantum dot structures may be CdSe, CdTe, CdSeTe, ZnCdSe, CdSeS, CdZnSeS, and the like.

In an embodiment, referring to FIG. 2, FIG. 2 is a flowchart of an embodiment of a method for preparing a quantum dot according to an embodiment of the present disclosure, the method for preparing a quantum dot includes following steps:
Step S11: mixing a cationic precursor and an anionic precursor with a first solvent and a second solvent to obtain a precursor solution;
Step S12: injecting the precursor solution into a reaction channel of a microfluidic reactor, and reacting at a preset reaction temperature to form the quantum dot.

In another embodiment, different raw materials and reagents configured to synthesize the quantum dot can be injected through a plurality of injection ports of the microfluidic reactor, and to realize mixing and reaction in the microfluidic reactor.

Before the step of mixing a cationic precursor, an anionic precursor with a first solvent and a second solvent to obtain a precursor solution, the method for preparing a quantum dot further includes: preparing the cation precursor and preparing the anion precursor. The cationic precursor and the anionic precursor may be in a solution state including a precursor solvent. The precursor solvent may include a certain amount of a first solvent and/or a certain amount of a second solvent.

In a specific embodiment, the cationic precursor is a cationic precursor solution. The preparation steps include: mixing a certain amount of a metal salt or a metal oxide with the precursor solvent; heating to a certain temperature in an inert gas atmosphere; heat preservation reacting for a certain time, and cooling a mixed system to a room temperature for standby to obtain a cationic precursor solution. An inert gas in the inert gas atmosphere can be argon gas, nitrogen gas, and the like. The inert gas atmosphere can remove air and moisture in the mixed system, and impurities with low boiling point in the mixed system can be removed in a heating environment. A temperature that the heating may reach ranges from 125° C. to 180° C. If the temperature is too low, the impurities in the system cannot be completely removed; if the temperature is too high, the solvent in the cationic precursor solution will be removed, and subsequent reaction will be affected. A time of the heat preservation reacting ranges from 30 minutes to 90 minutes. If the time of the heat preservation reacting is too short, the moisture and the impurities with low boiling point in the mixed system cannot be completely removed. If the time of the heat preservation reacting is too long, it is not conducive to improving synthesis efficiency.

Specifically, a metal in the metal salt may be at least one of zinc (Zn), cadmium (Cd), and the like. A salt in the metal salt may be at least one of an acetate, a palmitate, a stearate, a halogen salt, and the like. The halogen salt includes a chloride salt, a bromine salt, and the like. For example, the metal salt may be zinc acetate, zinc palmitate, zinc stearate, zinc chloride, zinc bromide, cadmium oleate, cadmium chloride, cadmium bromide, and the like. The metal oxide may be zinc oxide and/or cadmium oxide.

A concentration range of a cation in the cationic precursor solution is 0.05˜1 mol/L. If the concentration is too high, when the cationic precursor solution is subsequently taken to prepare the precursor solution, an amount of the cationic precursor solution will be less, thereby will lead to a large measurement error. However, if the concentration is too low, when the cationic precursor solution is mixed with the anionic precursor solution, the cationic precursor solution will be further diluted, which may lead to a failure to obtain the precursor solution with a preset cationic precursor concentration.

Moreover, the precursor solvent may include a certain amount of a first solvent and/or a certain amount of a second solvent. For example, the precursor solvent may include oleic acid and octadecene. Specifically, a volume ratio of oleic acid to octadecene is (1:1)˜(1:5). Excessive oleic acid will cause excessive viscosity of the cationic precursor solution, and excessive octadecene will lead to a decrease in the yield of the quantum dot and a low synthesis efficiency of the quantum dot.

In a specifically embodiment, preparation steps of the anionic precursor include: mixing, dispersing and dissolving a certain amount of a non-metallic powder and a ligand in an inert gas atmosphere; and heating to a certain temperature to obtain an anionic precursor solution. The ligand may be trioctyl phosphine (TOP), tributylphosphine, trihexylphosphine, and the like. The non-metallic powder may be a selenium (Se) powder, a sulfur(S) powder, a tellurium (Te) powder, and the like. A non-metal in the anionic precursor. The certain temperature is 80˜150° C. If the certain temperature is too low, dispersion of the non-metallic powder such as selenium powder is difficult and takes a long time. However, if the certain temperature is too high, the ligand such as trioctyl phosphine are easy to boil, thereby affect the accuracy of a concentration of the anionic precursor.

It can be understood that, the cationic precursor may be a single cationic precursor, or it may be two or more cationic precursors. Likewise, the anionic precursor may include a single anionic precursor, or two or more anionic precursors. Types, number of types and concentration ratio of the cationic precursor and the anionic precursor can be set according to a type of quantum dot synthesized according to specific needs.

Technical solutions and technical effects of the present disclosure are described in detail below by way of specific embodiments, the specific embodiments are only partial embodiments of the present disclosure and are not limited to the present disclosure.

### Example 1

Step 1: preparing a cationic precursor solution and an anionic precursor solution. The details are as follows:

Preparation of a Zn precursor solution (0.1 M): 0.440 g (2 mmol) of zinc acetate was added to 1.6 mL of OA and 18.4 mL of ODE solution, maintain under vacuum condition for 1 h, and then heated to 160° C. under a protection of nitrogen or argon for dissolution.

Preparation of Cd precursor solution (0.1 M): 0.256 g (2 mmol) cadmium oxide in 4.0 mL of OA and 16.0 mL of ODE, insulate under vacuum condition for 1 h, and then heated to 200° C. under a protection of nitrogen or argon for dissolution. when solution is clear, set a temperature to 90° C., evacuate at 90° C., and 30 minutes later, refill nitrogen or argon into a three-port flask and drop to room temperature to remove a heating sleeve, thus to obtain a cadmium oleate precursor solution.

Preparation of Se precursor solution (0.2 M): 2 mmol of selenium powder was dissolved in 10.0 mL TOP at 80° C.

Step 2: preparing a precursor solution: 10 mL of Zn precursor solution with a concentration of 0.1 M, 100 μL of Se precursor solution with a concentration of 0.2 M, and 2 mL of Cd precursor solution with a concentration of 0.2 M are respectively added to a liquid storage bottle containing a mixture solution of 70 mL of octadecane and 18 mL of n-hexane, and mixed evenly to obtain a precursor solution.

Step 3: microfluidic synthesising a quantum dot.

### Comparative Example 1

A difference between Comparative Example 1 and Example 1 is preparing a precursor solution in Step 2: 10 mL of Zn precursor solution with a concentration of 0.1 M, 100 μL of Se precursor solution with a concentration of 0.2 M, and 2 mL of Cd precursor solution with a concentration of 0.2 M are respectively added to a liquid storage bottle containing 88 mL of eighteen dilutes, and mixed evenly to obtain a precursor solution.

A microfluidic reactor used in the preparation method of the quantum dot of Comparative Example 1 and Example 1 can be referred to FIG. 1. The microfluidic reactor 10 has a chip structure, and includes a reaction channel 11, an injection channel 12, and an outflow channel 13. One end of the injection channel 12 is an injection port 121, and another end of the injection channel 12 is communicated with the reaction channel 11. One end of the reaction channel 11 is communicated with the injection channel 12, and another end of the reaction channel 11 is communicated with the outflow channel 13. One end of the outflow channel 13 communicates with the injection channel 12, and another end of the outflow channel 13 is a flow outlet 131. The microfluidic reactor 10 may include a plurality of injection channels 12, but in actual use, one or more of them may be selected to be used as required, and injection ports 121 of other injection channels 12 that are not required to be used may be sealed. The dotted box in FIG. 1 shows a heating zone A corresponding to the reaction channel 11. The reaction channel 11 and a reaction system flowing therein are heated to the reaction temperature by heating the heating zone A. In the microfluidic reactor 10, the reaction channel 11, the injection channel 12 and the outflow channel 13 have a same inner diameter of 750 μm, and a total volume of channels is 4 mL.

Steps of the microfluidic synthesising a quantum dots are show as following: injecting 10 mL of the precursor solution prepared above into a syringe pump through a control of microfluidic software; heating the heating zone A to a temperature of 260° C. through a control of a software of micro-fluidic heating system; controlling the injection pump by the microfluidic software to have the precursor solution enters the microfluidic reactor 10 at a flow rate of 10 μL/s after the temperature was stabilized, wherein the precursor solution entered from the injection port 121, and flowed through the injection channel 12 and the reaction channel 11 in turn; and heating reaction in reaction channel 11 to form a quantum dot of ZnₓCd₁₋ₓSe, a solution containing the quantum dot of ZnₓCd₁₋ₓSe flowed into the outflow channel 13 and flowed out of the microfluidic reactor 10 through the outlet 131 for collection.

In Example 1, continuous and large-scale synthesis preparation of the quantum dot was achieved by using a microfluidic reactor for reaction, and accurate control of a fluid reaction can be achieved at a micron-scale.

Fluorescence emission light of ZnCdSe blue quantum dots prepared according to Example 1 and Comparative Example 1 were detected, and plotted with fluorescence wavelength (nm) as abscissa and fluorescence Intensity (Intensity) as ordinate, to obtain a fluorescence emission spectrogram shown in FIG. 3. The solid line (a) corresponds to the quantum dot of Example 1, and the preparation of the quantum dot uses a high-low boiling point mixed solvent. The dotted line (b) corresponds to the quantum dot of Comparative Example 1, and the preparation of the quantum dot uses a conventional high-boiling point solvent. As can be seen from FIG. 3, a FWHM of Example 1 is 20 nm, a FWHM of Comparative Example 1 is 32 nm, and the FWHM of Example 1 is less than the FWHM of Comparative Example 1. The FWHM is a full width at half maximum of an emission spectrum which is configured to characterize the size distribution of the quantum dot. The smaller the FWHM, the narrower the size distribution of the quantum dot, and the more uniform the size of the quantum dot. Therefore, the size distribution of the quantum dot of Example 1 is narrower than that of the quantum dots of Comparative Example 1, and the size of the quantum dot of Example 1 is more uniform. Therefore, compared with the quantum dot prepared by using only the high-boiling point solvent of eighteen dilute in Comparative Example 1, the quantum dot prepared by reacting in the microfluidic reactor 10 as shown in FIG. 1 by using a mixed solvent of the high-boiling point solvent of eighteen dilute and the low-boiling point solvent of n-hexane in Example 1, the size distribution concentration of the quantum dot is improved, the size uniformity of the quantum dot is improved, thereby the overall quality of the quantum dot is improved.

The present disclosure further provides a quantum dot prepared by the above-mentioned preparation method. Specifically, the quantum dot may be selected from at least one of a single structure quantum dot and a core-shell structure quantum dot. A material of the single structure quantum dot may be selected from at least one of a group II-VI compound, a group III-V compound, and a group I-III-VI compound. The group II-VI compound is selected from at least one of CdSe, CdS, CdTe, ZnSe, ZnS, CdZnS, CdZnSe, CdZnTe, ZnSeS, ZnSeS, CdSeTe, ZnTeS, CdSeS, CdSeTe, CdSeS, CdSeTe, CdTeS, CdZnSeS, CdZnSeS, CdZnSeTe, and CdZnSTe. The group III-V compound is selected from at least one of InP, InAs, GaP, AlN, AlP, InAsP, InNP, InNSb, GaAlNP, and InAlNP. The group I-III-VI compound is selected from at least one of CuInS₂, CuInSe₂, and AgInS₂. A core of the core-shell structure quantum dot is selected from any one of the single structure quantum dot. A material of a shell of the core-shell structure quantum dot is selected from at least one of CdS, CdTe, CdSeTe, CdZnSe, CdZnS, CdSeS, ZnSe, ZnSeS, and ZnS.

The present disclosure further provides a quantum dot light-emitting device including a light-emitting layer. A material of the light-emitting layer may be the quantum dot described above. The quantum dot can be prepared by the method for preparing a quantum dot provided in the present disclosure.

Furthermore, the quantum dot light-emitting device may further include an electrode and/or a functional layer. The electrode may include a cathode and an anode. Materials of the cathode and the anode may be an electrode material known in the art. The functional layer may include an electron functional layer and a hole functional layer. For example, an electron transport layer, an electron injection layer, a hole transport layer, a hole injection layer, and the like. Specifically, materials of the electron functional layer and the hole functional layer are a corresponding functional layer materials known in the art, and will not be described here in detail.

The quantum dot and preparation method thereof, and the light-emitting device according to the embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

1. A method for preparing a quantum dot, comprising:
injecting a precursor solution into a reaction channel of a microfluidic reactor, and reacting at a preset reaction temperature to form a quantum dot;
wherein, the precursor solution comprises a first solvent and a second solvent, a boiling point of the first solvent is higher than a reaction temperature, and a boiling point of the second solvent is lower than the reaction temperature.

2. The method according to claim 1, wherein a volume ratio of the first solvent to the second solvent is (7-8):(2-3).

3. The method according to claim 1, wherein the reaction temperature is 250° C.-300° C.

4. The method according to claim 1, wherein the first solvent is selected from one or more of octadecene, liquid paraffin, oleamine, oleic acid, hexadecyl phosphoric acid, dodecylamine, and dodecyl mercaptan.

5. The method according to claim 1, wherein the second solvent is selected from an alkane with a carbon chain of 6 to 13 carbon atoms in length or an olefin with a carbon chain of 6 to 13 carbon atoms in length.

6. The method according to claim 5, wherein the second solvent is selected from one or more of n-hexane, n-heptane, n-octane, n-nonane, n-decane, n-undecane, and n-dodecane.

7. The method according to claim 1, wherein a flow rate of injecting a precursor solution into a reaction channel of a microfluidic reactor ranges from 1 to 10 μL/s.

8. The method according to claim 1, wherein a residence time of the precursor solution in the reaction channel is 5˜40 minutes.

9. The method according to claim 1, wherein the quantum dot is selected from one or more of a blue light quantum dot, a green light quantum dot, and a red light quantum dot.

10. The method according to claim 9, wherein the blue light quantum dot is selected from one or more of ZnTe, ZnSe, CdZnS, CdZnSe, ZnSeTe, ZnSTe, and ZnSeTe; the green light quantum dot is selected from one or more of CdSe, CdZnSeS, CdZnSe, and ZnSeTe; the red light quantum dot is selected from one or more of CdSe, CdTe, CdSeTe, ZnCdSe, CdSeS, and CdZnSeS.

11. The method according to claim 1, wherein before injecting a precursor solution into a reaction channel of a microfluidic reactor, the method further comprises:
mixing a cationic precursor and an anionic precursor with a first solvent and a second solvent to obtain the precursor solution.

12. The method according to claim 11, wherein before mixing a cationic precursor and an anionic precursor with a first solvent and a second solvent, the method further comprises:
preparing the cation precursor and preparing the anion precursor.

13. The method according to claim 12, wherein preparing the cation precursor comprises:
mixing a metal salt or a metal oxide with a precursor solvent, heating to a temperature of 125˜180° C. in an inert gas atmosphere, heat preservation reacting for 30-90 minutes to obtain the cation precursor in a solution state.

14. The method according to claim 13, wherein
the metal salt is selected from one or more of a zinc salt, a cadmium salt, an acetate, a palmitate, a stearate, and a halogen salt;
the metal oxide is selected from one or two of zinc oxide and cadmium oxide;
the precursor solvent comprises one or more of the first solvent and the second solvent;
a concentration range of a cation in the cationic precursor solution is 0.05˜1 mol/L.

15. The method according to claim 14, wherein the precursor solvent comprises oleic acid and octadecene, and a volume ratio of oleic acid to octadecene is (1:1)˜(1:5).

16. The method according to claim 12, wherein preparing the anion precursor comprises:
mixing, dispersing and dissolving a non-metallic powder and a ligand in an inert gas atmosphere under a temperature of 80˜150° C. to obtain the anionic precursor solution in a solution state.

17. The method according to claim 16, wherein the ligand is selected from one or more of trioctyl phosphine, tributylphosphine, and trihexylphosphine;
the non-metallic powder is selected from one or more of a selenium powder, a sulfur powder, and a tellurium powder.

18. A quantum dot, wherein the quantum dot is prepared by the method according to claim 1.

19. The method according to claim 18, wherein the quantum dot is selected from one or more of a single structure quantum dot and a core-shell structure quantum dot;
the single structure quantum dot is selected from one or more of a group II-VI compound, a group III-V compound, and a group I-III-VI compound; the group II-VI compound is selected from one or more of CdSe, CdS, CdTe, ZnSe, ZnS, CdZnS, CdZnSe, CdZnTe, ZnSeS, ZnSeS, CdSeTe, ZnTeS, CdSeS, CdSeTe, CdSeS, CdSeTe, CdTeS, CdZnSeS, CdZnSeS, CdZnSeTe, and CdZnSTe; the group III-V compound is selected from one or more of InP, InAs, GaP, AlN, AlP, InAsP, InNP, InNSb, GaAlNP, and InAlNP; the group I-III-VI compound is selected from one or more of CuInS₂, CuInSe₂, and AgInS₂;
a core of the core-shell structure quantum dot is selected from any one of the single structure quantum dot, and a material of a shell of the core-shell structure quantum dot is selected from one or more of CdS, CdTe, CdSeTe, CdZnSe, CdZnS, CdSeS, ZnSe, ZnSeS, and ZnS.

20. A light-emitting device comprising a light-emitting layer, wherein a material of the light-emitting layer is the quantum dot according to claim 18.
